(19) United States
(12) Patent Application Publication
(10) Pub. No.: US 2026/0237996 A1
(43) Pub. Date: Aug. 13, 2026

(54) POWER RECEIVING AND TRANSFORMING EQUIPMENT LEAKAGE CURRENT/STRAY CURRENT DIGITAL SAFETY CONTROL SYSTEM

(71) Applicant: TECHNOMIRAI Co., Ltd., Tokyo (JP)

(72) Inventor: Kazuo MIWA, Tokyo (JP)

(73) Assignee: TECHNOMIRAI Co., Ltd., Tokyo (JP)

(21) Appl. No.: 19/532,034

(22) Filed: Feb. 6, 2026

Related U.S. Application Data
(63) Continuation of application No. PCT/JP2025/004394, filed on Feb. 10, 2025.

(51) Int. Cl. H02H 5/04; G01K 3/00; G01R 19/00; G01R 31/52

(52) U.S. Cl. CPC H02H 5/04; G01K 3/005; G01R 19/0092; G01R 31/52

(57) ABSTRACT

A system monitors and controls power receiving and transforming equipment disposed on an electric path from a power-supply side to a plurality of loads. The system monitors and controls a step-down distribution transformer disposed in the power receiving and transforming equipment and electrical equipment such as a switchboard or a distribution board disposed on an electric path after stepping down with the transformer, thereby preventing occurrence of an electrical accident or the like leading to a fire or the like. The system constantly monitors a temperature of the transformer and an instantaneous current value of a current flowing through an electric path in the electrical equipment disposed on the electric path after stepping down with the transformer, and interrupts power supply to the load when a temperature of the transformer exceeds a predetermined value or when the instantaneous current value of a current exceeds a predetermined value.

### BACKGROUND

### Technical Field

### CROSS-REFERENCE TO RELATED APPLICATIONS

This application claims priority to and the benefit of International Application PCT/JP2025/004394, filed Feb. 10, 2025, under the Paris Convention, which is incorporated herein by reference in its entirety.

The present invention relates to a system that monitors and controls power receiving and transforming equipment disposed on an electric path from a power-supply side to a plurality of loads. The system is to monitor and control a step-down distribution transformer, that is, a high-voltage transformer disposed in the power receiving and transforming equipment, and to monitor and control electrical equipment disposed on an electric path after stepping down with the high-voltage transformer in the power receiving and transforming equipment. As a result, the system prevents occurrence of an electrical accident or the like leading to a fire or the like, and prevents occurrence of an accident causing damage or the like to various power/electric devices and apparatuses that are a plurality of the loads. Further, the present invention is a system for preventing occurrence of an electrical accident or the like due to short circuit, spark, tracking, or the like of a low-voltage switchboard, a distribution board, a control panel, a system main feeder, wiring, terminal electrical equipment, terminal load equipment, or the like in the power receiving and transforming equipment.

The applicant of the present application has already implemented DIGITAL ELECTRIC SAFETY CONTROL SYSTEM (Japanese Patent No. 6732278), named “DESCON”, which is a system for preventing occurrence of an electrical accident leading to a fire in a case where a power-source-side electric path from a power source side is electrically connected via a power device to a load-side electric path toward a load that operates by receiving power supply. In the above, the load-side electric path is an electric path toward a load that operates by receiving power supply, such as lighting equipment/device, air conditioning equipment/device, freezing and refrigeration equipment/device, and production equipment/device. In addition, in the above, the power device that electrically connects the power-source-side electric path and the load-side electric path is power receiving and transforming equipment, a switchboard, a distribution board, a lighting panelboard, a power panelboard, a control panel, a junction box, or the like, which are provided with electrical equipment such as a main breaker and an earth leakage breaker.

Further, the applicant of the present application has proposed a system, named “DESCON OPERATION SAFETY SYSTEM” (Japanese Patent No. 6991636), which is a system that can automatically perform ON/OFF switching of each of a plurality of loads to which a load-side electric path is connected, and automatically check a meter for a power usage amount in the load and automatically calculate the power usage amount, to save labor. This system prevents occurrence of an electrical accident leading to a fire by detecting bolt looseness in a bolt screw tightening connection portion in a power device, insufficient insertion into a receptacle, and leakage due to dust adhesion in the bolt screw tightening connection portion.

### SUMMARY

An object of the present invention is to propose a system that monitors and controls power receiving and transforming equipment disposed on an electric path from a power-supply side to a plurality of loads.

This system monitors and controls a step-down distribution transformer, that is, a high-voltage transformer disposed in the power receiving and transforming equipment, and monitors and controls electrical equipment disposed on an electric path after stepping down with the high-voltage transformer in the power receiving and transforming equipment.

By the monitoring and control described above, this system prevents occurrence of an electrical accident or the like leading to a fire or the like.

In addition, by the monitoring and control described above, this system prevents occurrence of an accident causing damage to various power/electric devices and apparatuses that are a plurality of the loads.

Further, by the monitoring and control described above, this system prevents occurrence of an electrical accident or the like due to short circuit, spark, tracking, or the like of a low-voltage switchboard, a distribution board, a control panel, a system main feeder, wiring, terminal electrical equipment, terminal load equipment, or the like in the power receiving and transforming equipment.

The present invention can be exemplified as follows.
[1] A power receiving and transforming equipment leakage current/stray current digital safety control system that monitors and controls power receiving and transforming equipment disposed on an electric path from a power-supply side to a plurality of loads, the power receiving and transforming equipment leakage current/stray current digital safety control system including:
   a transformer detection temperature value acquisition unit that is disposed for a transformer for step-down distribution disposed in the power receiving and transforming equipment and acquires a transformer detection temperature value T_{T}° C. that is a temperature of the transformer;
   an instantaneous current value acquisition unit that acquires an instantaneous alternating current value or an instantaneous direct current value that is an instantaneous current value i (amperes) of a current flowing in an instantaneous time in an electric path in electrical equipment that is disposed on the electric path after stepping down with the transformer in the power receiving and transforming equipment;
   a transformer temperature determination unit that compares the transformer detection temperature value T_{T}° C. with an allowable temperature range that is set in advance for a heat resistance class classified according to a heat resistance characteristic of an insulating material used in the transformer from which the transformer detection temperature value T_{T}° C. has been grasped;
   an instantaneous current value determination unit that compares the detected instantaneous current value i (amperes) with an allowable current value range that is set in advance for the electric path in the electrical equipment from which the instantaneous current value i (amperes) has been acquired by the instantaneous current value acquisition unit;
   a notification information transmission unit that outputs notification information to an administrator terminal used by an administrator who manages the power receiving and transforming equipment and/or an operator terminal used by an operator who is in charge of managing the power receiving and transforming equipment;
   a notification information level determination unit that determines a level of the notification information output by the notification information transmission unit, based on a comparison result by the transformer temperature determination unit and a comparison result by the instantaneous current value determination unit; and
   a power-supply automatic interruptibility determination unit, a first power supply interruption unit, and a second power supply interruption unit, in which
   the notification information level determination unit
   determines that a level of the notification information is caution notification information, when a comparison result by the transformer temperature determination unit indicates that the transformer detection temperature value T_{T}° C. has reached a caution trigger temperature within the allowable temperature range, and a comparison result by the instantaneous current value determination unit indicates that a caution trigger current value within the allowable current value range has not been reached,
   determines that a level of the notification information is the caution notification information, when a comparison result by the transformer temperature determination unit indicates that the transformer detection temperature value T_{T}° C. has not reached a caution trigger temperature within the allowable temperature range, and a comparison result by the instantaneous current value determination unit indicates that a caution trigger current value within the allowable current value range has been reached,
   determines that a level of the notification information is alert notification information that is the notification information of a type different from the caution notification information, when a comparison result by the transformer temperature determination unit indicates that the transformer detection temperature value T_{T}° C. has reached a caution trigger temperature within the allowable temperature range, and a comparison result by the instantaneous current value determination unit indicates that a caution trigger current value within the allowable current value range has been reached, and
   determines that a level of the notification information is the alert notification information, when a comparison result by the transformer temperature determination unit indicates that the transformer detection temperature value T_{T}° C. has reached an alert trigger temperature that is a temperature value higher than the caution trigger temperature within the allowable temperature range, or when a comparison result by the instantaneous current value determination unit indicates that an alert trigger current value that is a current value higher than the caution trigger current value within the allowable current value range has been reached,
   the notification information transmission unit outputs the notification information with the level determined by the notification information level determination unit,
   when the notification information level determination unit determines that a level of the notification information is the alert notification information, the power-supply automatic interruptibility determination unit determines whether a load is an automatically interruptible power supply load, for each of a plurality of the loads to which a current is supplied via the electrical equipment that is subjected to comparison by the instantaneous current value determination unit and from which the instantaneous current value i (amperes) has been acquired by the instantaneous current value acquisition unit,
   the first power supply interruption unit automatically interrupts power supply to the load determined as an automatically interruptible power supply load by the power-supply automatic interruptibility determination unit, and
   the second power supply interruption unit interrupts power supply to a load device controller controlling the load determined as not being an automatically interruptible power supply load by the power-supply automatic interruptibility determination unit, and then automatically interrupts power supply to the load.

### BRIEF DESCRIPTION OF DRAWINGS

FIG. 1 is a conceptual diagram illustrating a schematic configuration of power receiving and transforming equipment leakage current/stray current digital safety control system according to an embodiment of the present invention.

### DETAILED DESCRIPTION

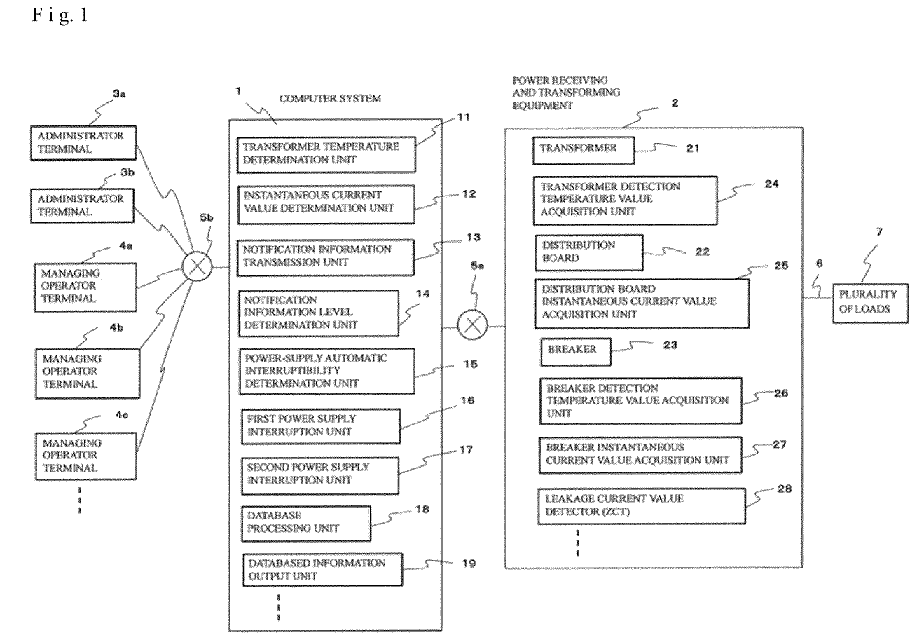

A power receiving and transforming equipment leakage current/stray current digital safety control system of the present invention is a system that monitors and controls power receiving and transforming equipment 2 disposed on an electric path 6 from a power-supply side to a plurality of loads 7 (FIG. 1). Note that, in the present specification and the drawings, the power receiving and transforming equipment leakage current/stray current digital safety control system of the present invention may be simply referred to as a “DESCON safety control system”.

The power receiving and transforming equipment usually includes a step-down distribution transformer and a plurality of pieces of electrical equipment disposed on an electric path after stepping down with the step-down distribution transformer. Examples of the plurality of pieces of electrical equipment disposed on the electric path after stepping down with the step-down distribution transformer in the power receiving and transforming equipment include a switchboard, a distribution board, a lighting panelboard, a power panelboard, a control panel, a remote controller panel, and the like, a junction box and the like for branch wiring connection of an extension cord or wiring between devices/instruments, a main breaker, an earth leakage breaker, and a circuit switch of a type different from the main breaker and the earth leakage breaker, such as a magnet switch, a power relay, and a solid state relay.

In FIG. 1, in order to simplify the description, only a step-down distribution transformer 21, and a distribution board 22 and a breaker 23 as electrical equipment disposed on the electric path after stepping down with the transformer 21 are illustrated in the power receiving and transforming equipment 2.

Examples of the plurality of loads 7 disposed at a destination of the electric path 6 from the power-supply side include power/electric apparatuses and devices that operate by receiving power supply, such as a prime mover, an elevator, air conditioning equipment, ventilation equipment, lighting equipment, a refrigerating/freezing case, a refrigerator/freezer, a measuring instrument, a computer device, a monitoring camera, a medical device, and a communication apparatus that are power/electric apparatuses and devices disposed and used regardless of whether inside or outside a building, power/electric apparatuses and devices and communication apparatuses and devices disposed and used in vehicles and moving means such as trains, cars, airplanes, and ships, and receptacles to which these are connected.

In addition, in a configuration in which power supply to the loads such as the measuring instrument, the computer device, the monitoring camera, the medical device, and the like described above is not automatically interruptible, and power supply to these loads is interrupted after interrupting of power supply to a load device controller controlling these loads, the load device controller and the like are also included in the plurality of loads.

The plurality of loads 7 are connected to a distal end side of the electric path 6 described above in which the power receiving and transforming equipment 2 to be monitored is interposed.

Heat resistance characteristic of the transformer of the power receiving and transforming equipment 2 is as follows, for example.

In the present specification and the drawings, the “transformer” may be indicated as “TR”, the “power receiving and transforming equipment” may be indicated as “cubicle”, and the “instantaneous AC current detector” (current transformer) may be indicated as “CT”.

The transformer 21 is classified into the following heat resistance classes in accordance with a heat resistance characteristic of an insulating material used in the transformer 21.

As the insulating material, a material such as insulating oil, SF6 gas, kraft paper, pressboard, mica, glass fiber, epoxy resin, silicon resin, or alkyd resin is used, and an allowable maximum temperature of the insulating oil to the alkyd resin is determined. In addition, in transformers using the various insulating materials described above, A is applied as a heat resistance class of an oil-filled transformer, and B, F, and H are applied as a mold transformer.

The transformer is designed such that, when the transformer is used in a standard use state, a temperature rise limit of winding (a limit of a difference between a temperature of the winding and an ambient temperature) is not exceeded, and a temperature of each part of an insulator does not exceed the allowable maximum temperature of the heat resistance class. However, the allowable maximum temperature may be exceeded when the ambient temperature exceeds a maximum value of 40° C., or excessive overload operation or the like is performed.

Since the service life of the transformer is most affected by a maximum point temperature, prolonged continuous operation with a temperature exceeding the allowable maximum temperature leads to reduction in the expected service life of the transformer, which is 30 years. An environment, configuration contents, and the like of the transformer are, for example, place for use: at an altitude of 1,000 m or less, ambient temperature: −5° C. to +40° C. for indoor and −20° C. to +40° C. for outdoor (a daily average temperature does not exceed 35° C. and an annual average temperature does not exceed 20° C.), circuit voltage waveform: a voltage waveform of a circuit to which the transformer is connected is substantially sinusoidal, and voltage balance of three-phase circuit: a three-phase circuit to which a three-phase transformer is connected is substantially balanced.

Since a resistance value changes according to a temperature of the winding, a reference winding temperature is defined as a temperature serving as a reference for calculating characteristic values such as load loss and short circuit impedance.

Regarding a heat resistance class and a temperature of the insulating material of TR (transformer), 140K is defined as a temperature rise limit in The Japan Electrical Manufacturers' Association, JEM 1310:2001 “Temperature rise limit and reference winding temperature (heat resistance class H) for dry-type transformers”.

Since a resistance value changes according to a temperature of the winding, a reference winding temperature is defined as a temperature serving as a reference for calculating characteristics such as load loss and short circuit impedance.

In 6 kV oil-filled distribution transformer (JIS C 4303:1999), an oil-filled reactor (JIS 4902:2003), a 6 kV molded distribution transformer (JIS C 4306), and a TR, boiling point of insulating oil is about 290° C. to 340° C.

The DESCON safety control system of the present invention includes a computer system 1 including a server computer or the like, and a transformer detection temperature value acquisition unit 24, a distribution board instantaneous current value acquisition unit 25, a breaker detection temperature value acquisition unit 26, a breaker instantaneous current value acquisition unit 27, a leakage current/stray current value detector ZCT 28, and the like to be described later, which are disposed in the power receiving and transforming equipment 2 to be monitored/controlled and are connected to the computer system 1 via a network 5a (FIG. 1).

Although not illustrated, the computer system 1 includes a CPU, a ROM, a RAM, a hard disk, and an information input/output unit such as a communication interface, and can include a computer having a configuration in which these are connected by a necessary bus line. The CPU performs control such that various functions of the system of this embodiment are implemented according to an operating system, a predetermined computer program installed or downloaded, or the like. The ROM stores an operating system, various computer programs, and the like, and functions as a storage unit that stores data necessary for the CPU to execute processing for each control. The RAM and the hard disk store data necessary for the CPU to execute processing, and are also used as a work area in which information is appropriately rewritten by the CPU.

In FIG. 1, in the computer system 1 including a storage unit (not illustrated), a transformer temperature determination unit 11, an instantaneous current value determination unit 12, a notification information transmission unit 13, a notification information level determination unit 14, a power-supply automatic interruptibility determination unit 15, a first power supply interruption unit 16, a second power supply interruption unit 17, a database processing unit 18, and a databased information output unit 19 are disposed.

Such a computer system executes processing operations to be described later performed by the transformer temperature determination unit 11, the instantaneous current value determination unit 12, the notification information transmission unit 13, the notification information level determination unit 14, the power-supply automatic interruptibility determination unit 15, the first power supply interruption unit 16, the second power supply interruption unit 17, the database processing unit 18, the databased information output unit 19, other processing units (not illustrated), and the like, and a tracking detection function, a Joule heat detection function, an overcurrent monitoring function, a leakage current monitoring function, and the like to be described later.

Further, in the embodiment illustrated in FIG. 1, in the power receiving and transforming equipment 2, the transformer detection temperature value acquisition unit 24 is disposed for the transformer 21, the distribution board instantaneous current value acquisition unit 25 is disposed for the distribution board 22, and the breaker detection temperature value acquisition unit 26, the breaker instantaneous current value acquisition unit 27, and the leakage current/stray current value detector (ZCT) 28 are disposed for the breaker 23.

In the embodiment illustrated in FIG. 1, the distribution board instantaneous current value acquisition unit 25 is an instantaneous current value acquisition unit that acquires an instantaneous alternating current value or an instantaneous direct current value which is an instantaneous current value of a current flowing in an instantaneous time in an electric path in electrical equipment disposed on the electric path after stepping down with the transformer 21 in the power receiving and transforming equipment 2, in the DESCON safety control system of the present invention.

Although not illustrated, it is also possible to adopt a configuration in which the electrical equipment disposed on the electric path after stepping down with the transformer 21 in the power receiving and transforming equipment 2 is a switchboard, and a switchboard instantaneous current value acquisition unit is disposed for the switchboard as the instantaneous current value acquisition unit that acquires an instantaneous alternating current value or an instantaneous direct current value which is an instantaneous current value of a current flowing in an instantaneous time in an electric path in the switchboard.

Further, in the embodiment illustrated in FIG. 1, the breaker instantaneous current value acquisition unit 27 corresponds to an example of a circuit breaker instantaneous current value acquisition unit in the present invention.

The distribution board instantaneous current value acquisition unit 25 is connected to the electric path in the distribution board 22, and detects an instantaneous alternating current value or an instantaneous direct current value which is an instantaneous current value of a current flowing in an instantaneous time through an electric path in the distribution board 22.

As the distribution board instantaneous current value acquisition unit 25, a current sensor using an instrument current transformer called a current transformer (CT) or a direct instantaneous current measuring instrument using a Hall element can be adopted.

In FIG. 1, the transformer detection temperature value acquisition unit 24, the distribution board instantaneous current value acquisition unit 25, the breaker detection temperature value acquisition unit 26, the breaker instantaneous current value acquisition unit 27, the leakage current/stray current value detector (ZCT) 28, and the computer system 1 are connected so as to be able to communicate information with each other via the wired or wireless network 5a such as the Internet or a dedicated line.

In addition, the computer system 1 is connected to a plurality of administrator terminals 3a, 3b, . . . and a plurality of operator terminals 4a, 4b, 4c, . . . so as to be able to communicate information with each other via a wired or wireless network 5b such as the Internet or a dedicated line.

The above-described administrator terminals 3a, 3b, . . . include an image information display unit such as a monitor, and can include personal computers or the like in which software for operating the system of the present invention is installed. In addition, the above-described operator terminals 4a, 4b, 4c, . . . can include portable terminals such as smartphones in which an application for operating the system of the present invention is downloaded.

The administrator terminals 3a, 3b, . . . and the operator terminals 4a, 4b, 4c, . . . are connected to the computer system 1 including a server computer or the like included in the DESCON safety control system of the present invention via the wired or wireless communication network 5b such as the Internet or a dedicated line so as to be able to communicate information with each other.

The above-described transformer detection temperature value acquisition unit 24 is disposed for the transformer 21, and performs processing of grasping a transformer detection temperature value T_{T}° C., which is a temperature of the transformer 21.

Transformer detection temperature value T_{T}° C. information is constantly monitored by the transformer detection temperature value acquisition unit 24 including a temperature sensor and the like, is output as digital information, and is delivered to the computer system 1 included in the DESCON safety control system of the present invention via the network 5a. The delivered transformer detection temperature value T_{T}° C. information is associated with information for identifying the transformer from which the transformer detection temperature value T_{T}° C. has been acquired, and is stored together with information regarding an acquisition time into a storage unit (not illustrated) of the computer system 1. The information regarding the acquisition time is recorded with the date down to the second, for example, which year, which month, which day, which hour, which minute, and which second.

Instantaneous current value i (amperes) (instantaneous alternating current value or instantaneous direct current value) information is constantly monitored by the distribution board instantaneous current value acquisition unit 25, is output as digital information, and is delivered to the computer system 1 included in the DESCON safety control system of the present invention via the network 5a. The delivered instantaneous current value i (amperes) is associated with information for identifying the electrical equipment from which the instantaneous current value i (amperes) has been acquired, and is stored together with information regarding an acquisition time into a storage unit (not illustrated) of the computer system 1. The information regarding the acquisition time is recorded with the date down to the second, for example, which year, which month, which day, which hour, which minute, and which second.

The instantaneous time can be arbitrarily set between 1/50,000 seconds (=20 μsec) and 1/100,000 seconds (=10 μsec). In addition, within this range, the instantaneous time can also be set in microseconds according to a performance of a computer (PC) included in the DESCON safety control system.

Setting the units of the instantaneous time in the detection in the instantaneous time in microseconds between 1/50,000 seconds (=20 μsec) and 1/100,000 seconds (=10 μsec) is advantageous for detecting a risk of occurrence of a tracking phenomenon earlier and taking necessary measures such as power interruption before the tracking phenomenon occurs.

The above-described transformer temperature determination unit 11 performs processing of comparing the transformer detection temperature value T_{T}° C. with a preset allowable temperature range for a heat resistance class classified according to a heat resistance characteristic of an insulating material used in the transformer 21 from which the transformer detection temperature value T_{T}° C. has been grasped.

Information regarding the preset allowable temperature range to be compared described above is stored in a storage unit (not illustrated) of the computer system 1.

The above-described instantaneous current value determination unit 12 performs processing of comparing the detected instantaneous current value with a preset allowable current value range for the electric path in the distribution board 22, which is electrical equipment from which the instantaneous current value has been acquired by the distribution board instantaneous current value acquisition unit 25. In this case, a storage unit (not illustrated) of the computer system 1 stores information regarding the preset allowable current value range, which is to be compared, for the electric path in the distribution board 22 which is the electrical equipment to be monitored.

The above-described notification information transmission unit 13 performs processing of outputting notification information to the administrator terminals 3a, 3b, . . . used by an administrator who manages the power receiving and transforming equipment 2 and/or the operator terminals 4a, 4b, 4c, . . . used by an operator who is in charge of managing the power receiving and transforming equipment 2.

The above-described notification information level determination unit 14 performs processing of determining a level of the notification information described above output by the notification information transmission unit 13 on the basis of a comparison result by the transformer temperature determination unit 11 and a comparison result by the instantaneous current value determination unit 12.

The determination processing performed by the notification information level determination unit 14 includes the following.

### First Determination Processing

When a comparison result by the transformer temperature determination unit 11 indicates that the above-described transformer detection temperature value T_{T}° C. has reached a caution trigger temperature within the above-described allowable temperature range, and a comparison result by the instantaneous current value determination unit 12 indicates that a caution trigger current value within the above-described allowable current value range has not been reached, it is determined that a level of the notification information is the caution notification information described above.

The notification information transmission unit 13 outputs the notification information with the level determined by the notification information level determination unit 14. That is, the notification information transmission unit 13 performs processing of outputting the above-described caution notification information as the notification information to the administrator terminals 3a, 3b, . . . and/or the operator terminals 4a, 4b, 4c, . . . on the basis of the above-described determination processing.

Note that an embodiment can be adopted in which, when the notification information transmission unit 13 outputs the caution notification information in this manner, the notification information transmission unit 13 adds, to the caution notification information to be output, information regarding the transformer detection temperature value T_{T}° C. in the transformer 21 subjected to the above-described determination by the notification information level determination unit 14 and information regarding the instantaneous current value i (amperes) in the electrical equipment (in the above case, the distribution board 22) subjected to the above-described determination by the notification information level determination unit 14.

As described above, the transformer detection temperature value T_{T}° C. information delivered to the computer system 1 included in the DESCON safety control system of the present invention is associated with information for identifying the transformer from which the transformer detection temperature value T_{T}° C. has been acquired, and is stored together with information regarding an acquisition time into a storage unit (not illustrated) of the computer system 1. The instantaneous current value i (amperes) similarly delivered is associated with information for identifying the electrical equipment from which the instantaneous current value i (amperes) has been acquired, and is stored together with information regarding an acquisition time into a storage unit (not illustrated) of the computer system 1.

By using these pieces of information, the output of the notification information performed by the notification information transmission unit 13 is added with information regarding the transformer detection temperature value T_{T}° C. in the transformer 21 subjected to the determination by the notification information level determination unit 14 and information regarding the instantaneous current value i (amperes) in the electrical equipment (in the above case, the distribution board 22) subjected to the determination by the notification information level determination unit 14.

### Second Determination Processing

When a comparison result by the transformer temperature determination unit 11 indicates that the above-described transformer detection temperature value T_{T}° C. has not reached the caution trigger temperature within the above-described allowable temperature range, and a comparison result by the instantaneous current value determination unit 12 indicates that the caution trigger current value within the above-described allowable current value range has been reached, it is determined that a level of the above-described notification information is the caution notification information described above.

The notification information transmission unit 13 outputs the notification information with the level determined by the notification information level determination unit 14. That is, the notification information transmission unit 13 performs processing of outputting the above-described caution notification information as the notification information to the administrator terminals 3a, 3b, . . . and/or the operator terminals 4a, 4b, 4c, . . . on the basis of the above-described determination processing.

Also in this case, as described above, an embodiment can be adopted in which the output of the notification information (caution notification information) performed by the notification information transmission unit 13 is added with information regarding the transformer detection temperature value T_{T}° C. in the transformer 21 subjected to the determination by the notification information level determination unit 14 and information regarding the instantaneous current value i (amperes) in the electrical equipment (in the above case, the distribution board 22) subjected to the determination by the notification information level determination unit 14.

### Third Determination Processing

When a comparison result by the transformer temperature determination unit 11 indicates that the above-described transformer detection temperature value T_{T}° C. has reached the caution trigger temperature within the above-described allowable temperature range, and a comparison result by the instantaneous current value determination unit 12 indicates that the caution trigger current value within the above-described allowable current value range has been reached, it is determined that a level of the notification information described above is the alert notification information that is notification information of a type different from the caution notification information described above.

The notification information transmission unit 13 outputs the notification information with the level determined by the notification information level determination unit 14. That is, the notification information transmission unit 13 performs processing of outputting the above-described alert notification information as the notification information to the administrator terminals 3a, 3b, . . . and/or the operator terminals 4a, 4b, 4c, . . . on the basis of the above-described determination processing.

Also in this case, as described above, an embodiment can be adopted in which the output of the notification information (alert notification information) performed by the notification information transmission unit 13 is added with information regarding the transformer detection temperature value T_{T}° C. in the transformer 21 subjected to the determination by the notification information level determination unit 14 and information regarding the instantaneous current value i (amperes) in the electrical equipment (in the above case, the distribution board 22) subjected to the determination by the notification information level determination unit 14.

### Fourth Determination Processing

When a comparison result by the transformer temperature determination unit 11 indicates that the above-described transformer detection temperature value T_{T}° C. has reached an alert trigger temperature that is a temperature value higher than the above-described caution trigger temperature within the above-described allowable temperature range, or when a comparison result by the instantaneous current value determination unit 12 indicates that an alert trigger current value, which is a current value higher than the caution trigger current value within the allowable current value range, has been reached, it is determined that a level of the notification information is the alert notification information described above.

The notification information transmission unit 13 outputs the notification information with the level determined by the notification information level determination unit 14. That is, the notification information transmission unit 13 performs processing of outputting the above-described alert notification information as the notification information to the administrator terminals 3a, 3b, . . . and/or the operator terminals 4a, 4b, 4c, . . . on the basis of the above-described determination processing.

Also in this case, as described above, an embodiment can be adopted in which the output of the notification information (alert notification information) performed by the notification information transmission unit 13 is added with information regarding the transformer detection temperature value T_{T}°C. in the transformer 21 subjected to the determination by the notification information level determination unit 14 and information regarding the instantaneous current value i (amperes) in the electrical equipment (in the above case, the distribution board 22) subjected to the determination by the notification information level determination unit 14.

In order to achieve an object of the present invention, the above-described allowable temperature range is arbitrarily set in advance within a range in which the object of the present invention can be achieved, for each heat resistance class classified according to a heat resistance characteristic of the insulating material used in the transformer, in consideration of the allowable maximum temperature that is set, as is known, for each heat resistance class (for example, A type insulation, E type insulation, B type insulation, F type insulation, and H type insulation) classified according to a heat resistance characteristic of the insulating material used in the transformer 21 to be monitored.

For example, in a case where the allowable maximum temperature of the transformer 21 to be monitored is 130° C. and the allowable maximum current value is 1718 A (amperes), in the range where the object of the present invention can be achieved, the allowable temperature range that is arbitrarily set in advance can be set to 120° C. to 135° C., similarly, the caution trigger temperature that is arbitrarily set in advance can be set to 130° C., and the alert trigger temperature can be set to 135° C.

The above-described allowable current value range that is set in advance for an electric path in electrical equipment from which the instantaneous current value has been acquired by the instantaneous current value acquisition unit can be, for example, a current value range allowed in advance corresponding to a cable size of the electric path in the electrical equipment from which the instantaneous current value has been acquired by the instantaneous current value acquisition unit.

For example, the allowable current value range set in advance corresponding to the cable size of the electric path in the electrical equipment from which the instantaneous current value has been acquired by the instantaneous current value acquisition unit may be 1.25 times or less a rated current set for the electric path of the cable size, the caution trigger current value arbitrarily set in advance may be set to 1.20 times or less the rated current set for the electric path of the cable size of the electrical equipment from which the instantaneous current value has been acquired by the instantaneous current value acquisition unit, and the alert trigger current value arbitrarily set in advance may be set to 1.25 times or less the rated current set for the electric path of the cable size the electrical equipment from which the instantaneous current value has been acquired by the instantaneous current value acquisition unit.

As described above, in the power receiving and transforming equipment leakage current/stray current digital safety control system of the present invention, a temperature of the step-down distribution transformer 21 in the power receiving and transforming equipment is constantly monitored, and an instantaneous current value is constantly monitored in an electric path in electrical equipment such as the switchboard or the distribution board disposed on an electric path after stepping down with the transformer 21 in the power receiving and transforming equipment.

Then, the caution information is output to the administrator and/or the operator when either one alone of the temperature and the instantaneous current value satisfies a predetermined caution information output condition, alert information that is caution information of a type different from the above-described caution information is output to the administrator and/or the operator when at least one of the temperature or the instantaneous current value satisfies a predetermined alert information output condition requiring management and control at a higher level than the above-described caution information output condition, and the above-described alert information is output to the administrator and/or the operator when both of the temperature and the instantaneous current value satisfy the predetermined caution information output condition described above.

In this way, a temperature of the step-down distribution transformer 21 in the power receiving and transforming equipment is constantly monitored, and an instantaneous current value is constantly monitored in an electric path in electrical equipment such as the switchboard or the distribution board disposed on the electric path after stepping down with the transformer 21 in the power receiving and transforming equipment. Then, once either one of the temperature and the instantaneous current value reaches, or both of the temperature and the instantaneous current value simultaneously reach the caution information output condition or the alert information output condition described above, the caution information or the alert information, which are different types of information, is output to the administrator and the operator. As a result, it is possible to prevent occurrence of an electrical accident or the like leading to a fire or the like, prevent occurrence of an accident causing damage to various power/electric devices and apparatuses that are a plurality of loads, and further prevent occurrence of an electrical accident or the like due to short circuit, spark, tracking, or the like of a low-voltage switchboard, a distribution board, a control panel, a system main feeder, wiring, terminal electrical equipment, terminal load equipment, or the like in the power receiving and transforming equipment.

When the notification information level determination unit 14 determines that a level of the notification information is the alert notification information, the power-supply automatic interruptibility determination unit 15 performs processing of determining whether a load is an automatically interruptible power supply load, for each load among the plurality of loads 7 to which a current is supplied via the electrical equipment (in the above description, the distribution board 22) from which the instantaneous current value acquisition unit (in the above description, the distribution board instantaneous current value acquisition unit 25) has acquired the instantaneous current value i (amperes) that has been subjected to comparison by the instantaneous current value determination unit 12.

Information on whether or not each of the plurality of loads 7 is an automatically interruptible power supply load, which is used in the determination processing, is stored in a storage unit (not illustrated) of the computer system 1.

In addition, the first power supply interruption unit 16 performs processing of automatically interrupting power supply to the load 7 determined as an automatically interruptible power supply load by the power-supply automatic interruptibility determination unit 15.

For example, in order to automatically interrupt power supply to the load 7 determined as an automatically interruptible power supply load by the power-supply automatic interruptibility determination unit 15, a processing operation unit of the computer system 1 transmits predetermined signal information to the power receiving and transforming equipment 2 via the above-described network 5a, and instructs a device such as the breaker 23 included in the power receiving and transforming equipment 2 to execute the automatic interruption of power supply described above.

Further, the second power supply interruption unit 17 performs processing of interrupting the power supply to the load device controller controlling the load 7 determined as not being an automatically interruptible power supply load by the power-supply automatic interruptibility determination unit 15, and then automatically interrupting the power supply to the load 7.

For example, the processing operation unit of the computer system 1 transmits predetermined signal information to the power receiving and transforming equipment 2 via the above-described network 5a so as to interrupt power supply to the load device controller controlling the load 7 determined as not being an automatically interruptible power supply load by the power-supply automatic interruptibility determination unit 15 and then automatically interrupt power supply to the load, to instruct a device such as the breaker 23 included in the power receiving and transforming equipment 2 to interrupt power supply to the above-described load device controller and then automatically interrupt power supply to the load.

The DESCON safety control system described above can be a system having a tracking detection function, by detecting an abnormal current, by converting an analog instantaneous alternating-current value or an analog instantaneous direct-current value detected by the above-described distribution board instantaneous current value acquisition unit 25 into an analog voltage value, converting the analog voltage value into a digital voltage value, and converting the digital voltage value into a current value.

The processing of detecting an abnormal current by converting an analog instantaneous alternating-current value or an analog instantaneous direct-current value detected by the distribution board instantaneous current value acquisition unit 25 into an analog voltage value, converting the analog voltage value into a digital voltage value, and converting the digital voltage value into a current value can be executed by a processing operation unit of the computer system 1 on the basis of an analog instantaneous current value (analog instantaneous alternating-current value or analog instantaneous direct-current value) acquired by the computer system 1. Alternatively, a microcomputer may be attached to the distribution board instantaneous current value acquisition unit 25, and the microcomputer may be caused to execute the above-described processing.

In a case where the electrical equipment from which the instantaneous current value is acquired by the above-described instantaneous current value acquisition unit is the circuit breaker (breaker) 23, or in a case where the circuit breaker (breaker) 23 is disposed on an electric path after stepping down with the transformer 21 in the power receiving and transforming equipment 2 in addition to the electrical equipment from which the instantaneous current value is acquired by the instantaneous current value acquisition unit, the DESCON safety control system can have a Joule heat detection function by further including the breaker detection temperature value acquisition unit 26 that monitors a temperature rise due to Joule heat of a connection terminal block of the electric path in the circuit breaker (breaker) 23.

In the configuration including the circuit breaker (breaker) 23, the breaker detection temperature value acquisition unit 26 that constantly monitors a temperature of the connection terminal block of the electric path in the circuit breaker (breaker) 23 is disposed for the circuit breaker (breaker) 23, and a temperature of the connection terminal block of the electric path in the circuit breaker (breaker) 23 is constantly monitored.

Connection terminal block detection temperature value information is constantly monitored by the breaker detection temperature value acquisition unit 26 including a temperature sensor and the like, is output as digital information, and is delivered to the computer system 1 included in the DESCON safety control system of the present invention via the network 5a such as the Internet or a dedicated line.

Since the temperature information of the connection terminal block of the electric path in the circuit breaker (breaker) 23 is based on Joule heat, the DESCON safety control system including the computer system 1 has a configuration having a Joule heat detection function by monitoring the acquired connection terminal block detection temperature value information.

Further, a mode can be adopted in which the breaker instantaneous current value acquisition unit 27 that monitors an overcurrent of the electric path in the circuit breaker (breaker) 23 is disposed for the circuit breaker (breaker) 23, and the overcurrent of the electric path in the circuit breaker (breaker) 23 is constantly monitored.

Connection terminal block detection overcurrent value information is constantly monitored by the breaker instantaneous current value acquisition unit 27, output as digital information, and is delivered to the computer system 1 included in the DESCON safety control system of the present invention via the network 5a.

Accordingly, the DESCON safety control system of the present invention can have a configuration having an overcurrent monitoring function by monitoring the acquired connection terminal block detection overcurrent value information.

As the breaker instantaneous current value acquisition unit 27, similarly to the above-described distribution board instantaneous current value acquisition unit 25, a current sensor using an instrument current transformer called a current transformer (CT) or a direct instantaneous current measuring instrument using a Hall element can be adopted.

Further, the instantaneous time can be arbitrarily set between 1/50,000 seconds (=20 μsec) and 1/100,000 seconds (=10 μsec). In addition, within this range, the instantaneous time can also be set in microseconds according to a performance of a computer (PC) included in the DESCON safety control system.

Moreover, a mode can be adopted in which the leakage current/stray current value detector zero-phase current transformer (ZCT) 28 that monitors a leakage current of the electric path in the circuit breaker (breaker) 23 is disposed in advance for the circuit breaker (breaker) 23, and a leakage current and a stray current of the electric path in the circuit breaker (breaker) 23 are constantly monitored.

Leakage current value information is constantly monitored by the leakage current/stray current value detector 28, is output as digital information, and is delivered to the computer system 1 included in the DESCON safety control system of the present invention via the network 5a.

Accordingly, the DESCON safety control system can have a configuration having a leakage current/stray current monitoring function by monitoring the acquired leakage current/stray current value information.

For example, it is also possible to include a unit (for example, the database processing unit 18) that constructs a database (not illustrated) in the computer system 1, by storing a leakage current as a caution leakage current and an alert leakage current, a stray current as a caution stray current and an alert stray current, and storing the leakage current, the stray current, and the like in units of, for example, seconds, minutes, hours, days, weeks, 10-day periods, months, three months of each season, six months, and years, and also by one year ago, two years ago, three years ago, . . . five years ago, . . . n years ago, and the like.

That is, the computer system 1 includes a database processing unit that stores a database obtained by converting, into a database, one or more types of information selected from among information regarding the transformer detection temperature value T_{T}°C. acquired by the transformer detection temperature value acquisition unit 24, information regarding an instantaneous direct current value detected by the distribution board instantaneous current value acquisition unit 25 that is an instantaneous current value acquisition unit, and information regarding a leakage current/stray current value grasped by the above-described leakage current/stray current value detector ZCT.

The transformer detection temperature value T_{T}° C. information acquired by the transformer detection temperature value acquisition unit 24 is associated with information for identifying the transformer from which the transformer detection temperature value T_{T}° C. has been acquired, and is stored together with information regarding an acquisition time into a storage unit (not illustrated) of the computer system 1. Instantaneous current value i (amperes) (instantaneous alternating current value or instantaneous direct current value) information acquired by the distribution board instantaneous current value acquisition unit 25 is associated with information for identifying the electrical equipment from which the instantaneous current value i (amperes) has been acquired, and is stored together with information regarding an acquisition time into a storage unit (not illustrated) of the computer system 1. The information regarding the leakage current value and the stray current value grasped by the leakage current/stray current value detector ZCT is associated with information for identifying the breaker 23, and is stored in a storage unit (not illustrated) of the computer system 1 together with information regarding an acquisition time.

Here, a configuration may be adopted in which these pieces of information are converted into a database by the above-described unit (for example, the database processing unit 18) that performs conversion into a database, information corresponding to an information provision request is extracted from the database when the information provision request is received from any one of the administrator terminals 3a, 3b, . . . , and the operator terminals 4a, 4b, 4c, . . . via the network 5b to the computer system 1, and the extracted information is transmitted from the computer system 1 via the network 5b to the one of the administrator terminals 3a, 3b, . . . , and the operator terminals 4a, 4b, 4c, . . . that has made the information provision request.

That is, the computer system 1 includes the databased information output unit 19 that extracts information corresponding to an information provision request from the database when the information provision request is received from any one of the administrator terminal 3a, 3b, . . . and the operator terminal 4a, 4b, 4c, . . . , and transmits the extracted information to the one of the administrator terminal 3a, 3b, . . . and the operator terminal 4a, 4b, 4c, . . . that has made the information provision request.

It is not necessary that all the processing operation units such as the transformer temperature determination unit 11, the instantaneous current value determination unit 12, the notification information transmission unit 13, and the notification information level determination unit 14 described above are disposed in one apparatus/device.

For example, a mode may be adopted in which an apparatus/device having some of these configurations is disposed in the power receiving and transforming equipment 2 to be monitored/controlled, and the apparatus/device is connected to another apparatus/device that is disposed at a place away from the power receiving and transforming equipment 2 and includes a computer having other configurations so as to be able to communicate information via a wired or wireless network.

Alternatively, it is also possible to adopt a mode in which an apparatus/device having some of the configurations described above is disposed in the power receiving and transforming equipment to be monitored/controlled, and the apparatus/device is connected to another apparatus/device that is disposed away from the power receiving and transforming equipment and includes a computer having some of other configurations and another apparatus/device including a computer having remaining configurations among other configurations so as to be able to communicate information via a wired or wireless network.

In the above, it is also possible to adopt a configuration in which a server computer disposed on a cloud is included in one or a plurality of other apparatuses/devices that are disposed at a place away from the power receiving and transforming equipment 2, are connected via a wired or wireless network, and have some configurations or remaining configurations among other configurations described above.

Although the embodiment of the present invention has been described above, the present invention is not limited to the above-described embodiment, and various modifications can be made within the technical scope understood from the description of the claims.

1. A digital safety control system for monitoring and controlling leakage current and/or stray current on an electric path from a power-supply side of power receiving and transforming equipment to a plurality of loads, the power receiving and transforming equipment including a transformer for step-down distribution, the digital safety control system comprising:
a transformer detection temperature value acquisition unit that is disposed for the transformer for step-down distribution disposed in the power receiving and transforming equipment and acquires a transformer detection temperature value T_{T}° C. that is a temperature of the transformer;
an instantaneous current value acquisition unit that acquires an instantaneous alternating current value or an instantaneous direct current value that is an instantaneous current value i (amperes) of a current flowing in an instantaneous time in an electric path in electrical equipment that is disposed on the electric path after stepping down with the transformer in the power receiving and transforming equipment;
a transformer temperature determination unit that compares the transformer detection temperature value T_{T}° C. with an allowable temperature range that is set in advance for a heat resistance class classified according to a heat resistance characteristic of an insulating material used in the transformer from which the transformer detection temperature value T_{T}° C. has been grasped;
an instantaneous current value determination unit that compares the detected instantaneous current value i (amperes) with an allowable current value range that is set in advance for the electric path in the electrical equipment from which the instantaneous current value i (amperes) has been acquired by the instantaneous current value acquisition unit;
a notification information transmission unit that outputs notification information to an administrator terminal used by an administrator who manages the power receiving and transforming equipment and/or an operator terminal used by an operator who is in charge of managing the power receiving and transforming equipment;
a notification information level determination unit that determines a level of the notification information output by the notification information transmission unit, based on a comparison result by the transformer temperature determination unit and a comparison result by the instantaneous current value determination unit; and
a power-supply automatic interruptibility determination unit, a first power supply interruption unit, and a second power supply interruption unit, wherein
the notification information level determination unit
determines that a level of the notification information is caution notification information, when a comparison result by the transformer temperature determination unit indicates that the transformer detection temperature value T_{T}° C. has reached a caution trigger temperature within the allowable temperature range, and a comparison result by the instantaneous current value determination unit indicates that a caution trigger current value within the allowable current value range has not been reached,
determines that a level of the notification information is the caution notification information, when a comparison result by the transformer temperature determination unit indicates that the transformer detection temperature value T_{T}° C. has not reached a caution trigger temperature within the allowable temperature range, and a comparison result by the instantaneous current value determination unit indicates that a caution trigger current value within the allowable current value range has been reached,
determines that a level of the notification information is alert notification information that is the notification information of a type different from the caution notification information, when a comparison result by the transformer temperature determination unit indicates that the transformer detection temperature value T_{T}° C. has reached a caution trigger temperature within the allowable temperature range, and a comparison result by the instantaneous current value determination unit indicates that a caution trigger current value within the allowable current value range has been reached, and
determines that a level of the notification information is the alert notification information, when a comparison result by the transformer temperature determination unit indicates that the transformer detection temperature value T_{T}° C. has reached an alert trigger temperature that is a temperature value higher than the caution trigger temperature within the allowable temperature range, or when a comparison result by the instantaneous current value determination unit indicates that an alert trigger current value that is a current value higher than the caution trigger current value within the allowable current value range has been reached,
the notification information transmission unit outputs the notification information with the level determined by the notification information level determination unit,
when the notification information level determination unit determines that a level of the notification information is the alert notification information, the power-supply automatic interruptibility determination unit determines whether a load is an automatically interruptible power supply load, for each of a plurality of the loads to which a current is supplied via the electrical equipment that is subjected to comparison by the instantaneous current value determination unit and from which the instantaneous current value i (amperes) has been acquired by the instantaneous current value acquisition unit,
the first power supply interruption unit automatically interrupts power supply to the load determined as an automatically interruptible power supply load by the power-supply automatic interruptibility determination unit, and
the second power supply interruption unit interrupts power supply to a load device controller controlling the load determined as not being an automatically interruptible power supply load by the power-supply automatic interruptibility determination unit, and then automatically interrupts power supply to the load.

2. The digital safety control system according to claim 1, wherein output of the notification information performed by the notification information transmission unit is added with: information regarding the transformer detection temperature value T_{T}° C. of the transformer subjected to determination by the notification information level determination unit; and information regarding the instantaneous current value i (amperes) in the electrical equipment subjected to determination by the notification information level determination unit.

3. The digital safety control system according to claim 1, wherein the instantaneous time is any given microsecond time within a range of 1/50,000 second (=20 μsec) to 1/100,000 second (=10 μsec).

4. The digital safety control system according to claim 3, having a tracking detection function of detecting an abnormal current, by converting an analog instantaneous alternating-current value or an analog instantaneous direct-current value detected by the instantaneous current value acquisition unit into an analog voltage value, converting the analog voltage value into a digital voltage value, and converting the digital voltage value into a current value.

5. The digital safety control system according to claim 3, wherein
in a case where the electrical equipment from which the instantaneous current value is acquired by the instantaneous current value acquisition unit is a circuit breaker (breaker), or in a case where a circuit breaker (breaker) is disposed on an electric path after stepping down with the transformer in the power receiving and transforming equipment in addition to the electrical equipment from which the instantaneous current value is acquired by the instantaneous current value acquisition unit,
the power receiving and transforming equipment leakage current/stray current digital safety control system has a Joule heat detection function by further comprising a breaker detection temperature value acquisition unit that monitors a temperature rise due to Joule heat of a connection terminal block of the electric path in the circuit breaker (breaker).

6. The digital safety control system according to claim 5, having an overcurrent monitoring function by further comprising a circuit breaker instantaneous current value acquisition unit that monitors an overcurrent of the electric path in the circuit breaker (breaker).

7. The digital safety control system according to claim 5, having a leakage current/stray current monitoring function by further comprising a leakage current/stray current value detector zero-phase current transformer (ZCT) that monitors a leakage current of the electric path in the circuit breaker (breaker).

8. The digital safety control system according to claim 6, having a leakage current/stray current monitoring function by further comprising a leakage current/stray current value detector zero-phase current transformer (ZCT) that monitors a leakage current of the electric path in the circuit breaker (breaker).

9. The digital safety control system according to claim 7, further comprising a database processing unit that stores a database obtained by converting, into a database, one or more types of information selected from among information regarding the transformer detection temperature value T_{T}° C. acquired by the transformer detection temperature value acquisition unit, information regarding the instantaneous direct current value detected by the instantaneous current value acquisition unit, and information regarding a leakage current/stray current value grasped by the leakage current/stray current value detector ZCT.

10. The digital safety control system according to claim 9, further comprising a databased information output unit, wherein, when the databased information output unit receives an information provision request from the administrator terminal or the operator terminal, the databased information output unit extracts information corresponding to the information provision request from the database, and transmits the information to the administrator terminal or the operator terminal that has transmitted the information provision request.
